(19) United States
(12) Patent Application Publication
(10) Pub. No.: US 2025/0314727 A1
(43) Pub. Date: Oct. 9, 2025

(54) FLEXIBLE NO PHASE WRAP USING OUTER VOLUME SUPPRESSION FOR TWO-DIMENSIONAL MAGNETIC RESONANCE IMAGING

(71) Applicant: GE Precision Healthcare LLC, Waukesha, WI (US)

(72) Inventors: Anand Venkatachari, Brookfield, WI (US); Ajeetkumar Gaddipati, Waukesha, WI (US)

(21) Appl. No.: 18/625,436

(22) Filed: Apr. 3, 2024

(51) Int. Cl. G01R 33/54; G01R 33/483; G01R 33/565

(52) U.S. Cl. CPC G01R 33/543; G01R 33/4838; G01R 33/56545

(57) ABSTRACT

A flexible no phase wrap (NPW) protocol using outer volume suppression (OVS) for reducing scan time in two-dimensional (2D) magnetic resonance imaging (MRI) is described. According to an example, a method comprises controlling, by a device comprising a processor, acquisition of a signal data associated with a region of interest (ROI) within an anatomical region of a subject using a using a MRI system, wherein the controlling comprises employing a combination of an OVS protocol and a NPW protocol with 2D MRI process. The method further comprises reconstructing, by the device, an image of the ROI from the signal data. Based on employing the combination, the phase field-of-view (FOV) can be reduced while still minimizing or eliminating wrap-around artifacts in the image, thereby reducing the scan time duration.

### TECHNICAL FIELD

This application relates to two-dimensional (2D) magnetic resonance imaging (MRI) and more particularly to a flexible no phase wrap (NPW) protocol using outer volume suppression (OVS) for reducing scan time.

### BACKGROUND

No phase wrap (NPW), also known as phase oversampling, is a technique used in magnetic resonance imaging (MRI) to reduce or eliminate wrap-around artifacts. Wrap-around artifacts (also referred to as fold-over artifacts) are typically observed in small field-of-view (FOV) imaging, which refers to capturing an MRI image with a defined FOV corresponding to a portion of an anatomical object of a subject. A wrap-around artifact, a form of aliasing, occurs when the anatomic dimensions of the object exceed the defined FOV. The portions of the object outside the defined FOV are misidentified during image reconstruction in terms of phase and are folded over into the image from the periphery, creating discontinuities or errors in the resulting image, referred to as wrap-around artifacts (or similar terms). Wrap-around artifacts can distort the image and make it difficult to interpret accurately.

Most MRI vendors offer NPW methods to control wrap-around artifacts, with the nomenclature varying amongst the major vendors (e.g., sometimes referred to as NPW, but also referred to as phase-oversampling, fold-over suppression, anti-wrap, phase-wrap suppression, and others). With only minor variations between vendors, all NPW methods involve increasing the acquisition FOV beyond the target portion of the object in the phase encoding direction and increasing the number of phase encoding steps accordingly to maintain the same spatial resolution. The acquired signal data is used to reconstruct an image with the acquisition FOV, which is then cropped to include only the middle portion corresponding to the target portion of the object.

Although this technique can effectively eliminate or reduce wrap-around artifacts in the final image, because the acquisition FOV and the number of phase encoding steps is increased, the duration of the acquisition time (or the scan time) is also proportionally increased. For example, by doubling the acquisition FOV and the number of phase encoding steps, the duration of the acquisition time is also doubled.

Reducing MRI scan times has remained an ongoing goal in MRI technology innovation. Shorter scan times improve the overall efficiency of MRI operations. Healthcare providers can schedule more patients per day, optimize resource utilization, and streamline workflow processes, leading to cost savings and increased productivity. Shorter scan times also improve the patient experience by reducing the duration of time the patient spends in the MRI scanner, reducing anxiety and discomfort during the procedure. In addition, motion artifacts caused by patient movement can degrade image quality and compromise diagnostic accuracy. By reducing scan times, the risk of motion artifacts is minimized, resulting in sharper and more reliable images for interpretation by radiologists and clinicians.

Accordingly, techniques for eliminating and minimizing wrap-around artifacts with a lower impact on scan time are desired.

### SUMMARY

The following presents a summary to provide a basic understanding of one or more embodiments of the invention. This summary is not intended to identify key or critical elements or delineate any scope of the different embodiments or any scope of the claims. Its sole purpose is to present concepts in a simplified form as a prelude to the more detailed description that is presented later. In one or more embodiments, systems, computer-implemented methods, apparatus and/or computer program products are described that facilitate a flexible no phase wrap protocol using outer volume suppression for reducing scan time in two-dimensional (2D) MRI.

According to an embodiment, an MRI system is provided that comprises at least one memory that stores computer-executable components, and at least one processor that executes the computer-executable components stored in the at least one memory. The computer-executable components comprise a control component that controls acquisition of a signal data associated with a region of interest (ROI) within an anatomical region of a subject via the MRI system using a combination of an outer volume suppression (OVS) protocol and a no phase wrap (NPW) protocol with a two-dimensional (2D) MRI process. The 2D MRI process can include any 2D MRI process, such as but not limited to a 2D spin echo (SE) process, a 2D fast spin echo (FSE)/2D turbo spin echo (TSE) process. The computer-executable components further comprise a reconstruction component that generates an image of the ROI from the signal data.

In accordance with the disclosed MRI system, based on using the combination of the OVS protocol and the NPW protocol with the 2D MRI process, the image comprises a defined image quality and a duration of the acquisition of the signal data is reduced relative to another acquisition duration of a variation of the 2D MRI process employable to generate a corresponding image of the ROI with the defined image quality, the variation comprising the NPW protocol and excluding the OVS protocol. The defined image quality can comprise an absence of wrap-around artifacts or an amount of the wrap-around artifacts being less than a defined amount. In this regard, the NPW protocol comprises applying a NPW parameter that controls a phase field-of-view (PFOV) of the signal data in a phase encoding direction of the 2D MRI process, and wherein the employing comprises employing a reduced value for the NPW parameter as a result of the employing the combination relative to another value for the NPW parameter employable to generate the corresponding image of the ROI with the defined image quality using the variation of the 2D MRI process.

The OVS protocol comprises employing a pulse sequence that comprises one or two radio frequency (RF) pulses configured to suppress magnetic resonance signals in one or more volume regions of the slice outside the ROI in the phase encoding direction. In various embodiments, the value of the NPW parameter is variable, and wherein the PFOV and the duration of the acquisition of the signal data increases as the value of the NPW parameter increases.

In some embodiments, elements described in the disclosed systems can be embodied in different forms such as a computer-implemented method, a computer program product, or another form.

### DESCRIPTION OF THE DRAWINGS

FIG. 1 presents an example MRI system in accordance with one or more embodiments of the disclosed subject matter.

FIG. 2 presents an example operating device of an MRI system that facilitates controlling acquisition of 2D MRI images using a combination of a NPW protocol and an OVS protocol, in accordance with one or more embodiments of the disclosed subject matter.

FIG. 3 presents an example 2D FSE waveform with one pair of OVS pulses, in accordance with one or more embodiments of the disclosed subject matter.

FIG. 4A presents an image of phantom objects in an example MRI scanner used to create an example phantom image shown in FIGS. 4B-5C.

FIG. 4B illustrates defining a phase field-of-view (PFOV) with respect to the example phantom scout image in accordance with a NPW protocol.

FIG. 4C illustrates defining a PFOV and an OVS region with respect to the example phantom scout image in accordance with a combination of a NPW protocol and an OVS protocol, in accordance with one or more embodiments of the disclosed subject matter.

FIGS. 5A and 5B illustrate different phantom MRI images resulting from using different NPW parameter values and a NPW protocol only, in accordance with one or more embodiments of the disclosed subject matter.

FIG. 5C illustrates an example phantom MRI image resulting from using a combination of a NPW protocol and OVS protocol, in accordance with one or more embodiments of the disclosed subject matter.

FIGS. 6A-6C present different versions of orbit MRI images resulting from different acquisition parameters, in accordance with one or more embodiments of the disclosed subject matter.

FIG. 7 presents a high-level flow diagram of an example computer-implemented method for performing a 2D MRI process using a combination of an OVS protocol and a NPW protocol, in accordance with one or more embodiments of the disclosed subject matter.

FIG. 8 presents a high-level flow diagram of another example computer-implemented method for performing a 2D MRI process using a combination of an OVS protocol and a NPW protocol, in accordance with one or more embodiments of the disclosed subject matter.

FIG. 9 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background section, Summary section or in the Detailed Description section.

The disclosed subject matter is directed to systems, computer-implemented methods, apparatus and/or computer program products that provide a flexible no phase wrap (NPW) protocol using outer volume suppression (OVS) for reducing scan time in 2D MRI. To this end, as noted in the Background Section, although the NPW technique can effectively minimize or eliminate wrap around artifacts, because such technique increases the FOV in the phase encoding direction and the number of phase encoding steps, the NPW technique increases the scan time or signal acquisition time.

The disclosed techniques combine a flexible NPW protocol with an OVS protocol to minimize or eliminate wrap around artifacts in the resulting image acquired in accordance with a 2D MRI process while also reducing the signal acquisition time. The OVS protocol integrates one or more suppression RF pulses prior to the initial excitation pulse of the 2D MRI pulse sequence employed to acquire the signal data used to generate the image via the MRI system. The OVS slice thickness in the phase encoding direction is automatically determined based on the selected target FOV, the NPW parameter value (or the corresponding phase field-of-view (PFOV) resulting therefrom) and the overall object length in the phase encoding direction. The OVS pulses are configured to suppress signals acquired from tissues in one or more outer volume regions outside the PFOV in the phase encoding direction. As a result, the PFOV defined by the NPW parameter value and the corresponding number of phase encoding steps can be reduced, thereby reducing the signal acquisition time.

The MRI pulse sequence can include any 2D MRI pulse sequence configured to acquire signal data corresponding to only a cross-sectional view or slice of an anatomical region of the subject scanned. For example, the MRI pulse sequence can include a 2D spin echo sequence, a 2D fast spin echo sequence (FSE)/turbo spine echo sequence (TSE), or another 2D MRI pulse sequence. In this regard, the disclosed techniques are specifically designed for 2D MRI as opposed to 3D MRI.

As used herein, 2D MRI refers to an MRI process in which MR data is acquired in a series of 2D slices, each representing a cross-sectional view of the imaged anatomy. The MRI scanner acquires data one slice at a time, with each slice being acquired sequentially using pulse sequences tailored to the desired imaging plane (e.g., axial, sagittal, or coronal). Each 2D slice is reconstructed independently to generate a single 2D image. On the other hand, in 3D MRI, imaging data is acquired volumetrically, covering the entire imaging volume in three dimensions. The MRI scanner acquires data in a single continuous 3D volume, typically using a 3D imaging sequence such as 3D gradient echo or 3D TSE. The acquired 3D volume contains information about the entire imaged anatomy in three dimensions, without the need for sequential slice acquisitions. Reconstruction of 3D MRI data involves processing the entire volumetric dataset to generate a series of contiguous slices or multiplanar reformats (MPRs) in any desired orientation.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

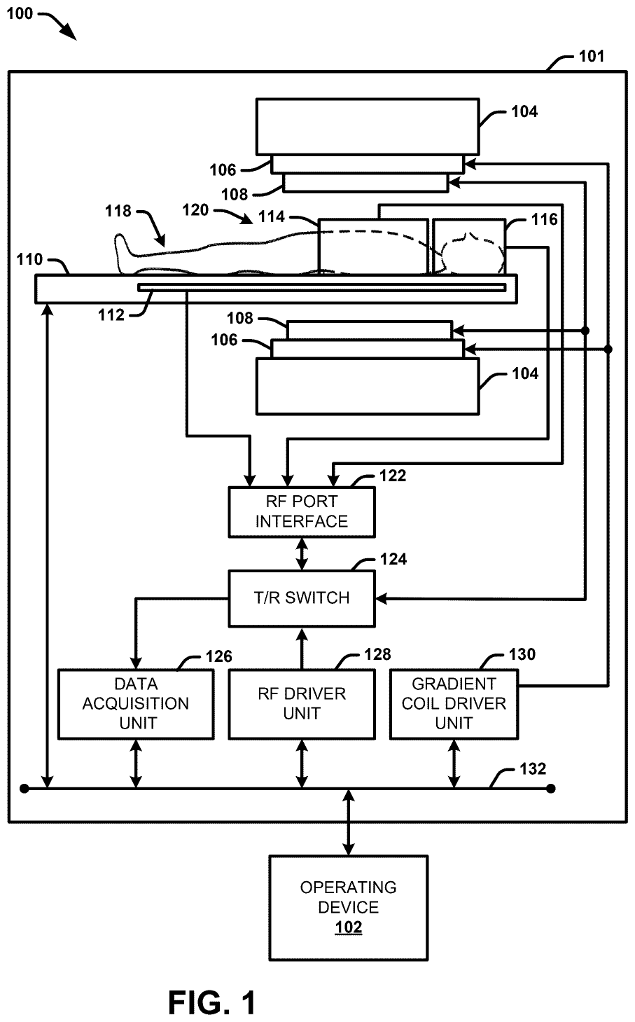

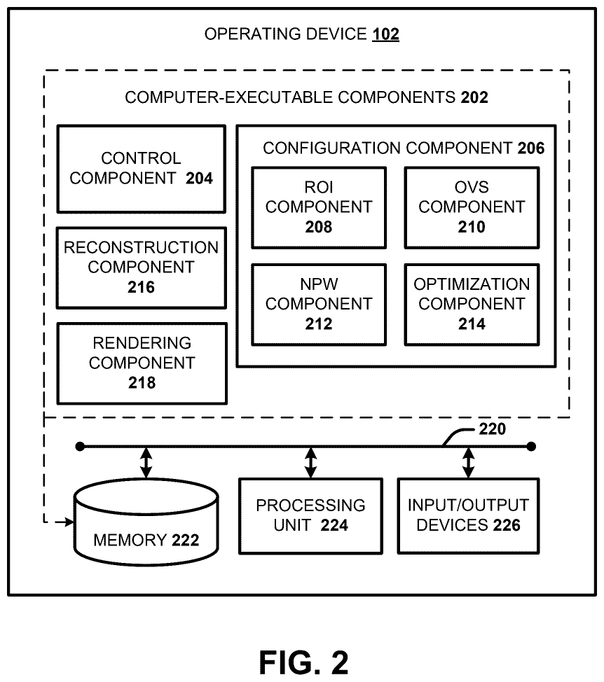

Turning now to the drawings, FIG. 1 illustrates an example MRI system 100 in accordance with one or more embodiments of the disclosed subject matter. MRI system 100 includes an MRI machine 101 and an operating device 102 that controls operations of the MRI machine 101. The operating device 102 can be communicatively and operatively connected to the MRI machine 101 (and/or respective elements thereof) via a system bus 132 and/or via any suitable wired or wireless communication network. The operating device 102 can include or correspond to one or more computing devices that control operations of the MRI machine 101, including controlling acquisition of magnetic resonance (MR) signal data (e.g., via the data acquisition unit 126) associated with an anatomical region of a subject 118 used to reconstruct an image of the anatomical region. The operating device 102 also receives the acquired MR signal data and performs image reconstruction using the MR signal data to generate the image. The operating device 102 can further display (e.g., via a suitable electronic display associated with the operating device 102) the reconstructed image, store the image, and/or send the image to another system/device. Additionally details regarding the features and functionalities of the operating device 102 are described below with reference to FIG. 2.

The MRI machine 101 can include or correspond to any existing or future MRI machine capable of performing any existing or future 2D MRI process (e.g., a spin echo process, a FSE process, a TSE process, or the like). Generally, the MRI machine 101 works based on the principles of nuclear magnetic resonance (NMR) and utilizes a combination of strong magnetic fields, radiofrequency (RF) pulses, and computer processing (performed via data acquisition unit 126 and operating device 102) to produce detailed images inside the body.

In this regard, the human body is composed largely of water molecules, which contain hydrogen atoms. When a subject 118 enters the MRI machine 101, the hydrogen nuclei (protons) within their body align with a strong, constant and uniform magnetic field generated by the MRI machine 101. This main magnetic field is generally referred to B₀. The MRI machine generates brief RF pulses directed to the area of the body of the subject 118 being imaged. The RF pulses are tuned to the resonant frequency of the protons in the body, which is determined by the strength of the main magnetic field B₀. When the RF pulse is applied, it perturbs the alignment of the protons, causing them to absorb energy and move out of alignment with the main magnetic field B₀. This process is known as excitation. After the RF pulse is turned off, the hydrogen nuclei gradually return to their original alignment with the main magnetic field B₀. As they do so, they emit RF signals, a process known as relaxation.

RF coils within the MRI machine 101 detect the RF signals emitted by the relaxing protons. These RF signals contain information about the spatial distribution of protons within the body. The detected RF signals are converted into electrical signals (e.g., via data acquisition unit 126) and sent to a computer (e.g., operating device 102) for processing. The computer collects and organizes the signals based on their spatial information and signal strength, storing them as raw data. Using sophisticated algorithms, the computer processes the raw data to reconstruct a detailed image of the inside of the body. Different tissues within the body produce varying signals based on their composition and structure, resulting in contrast in the final image.

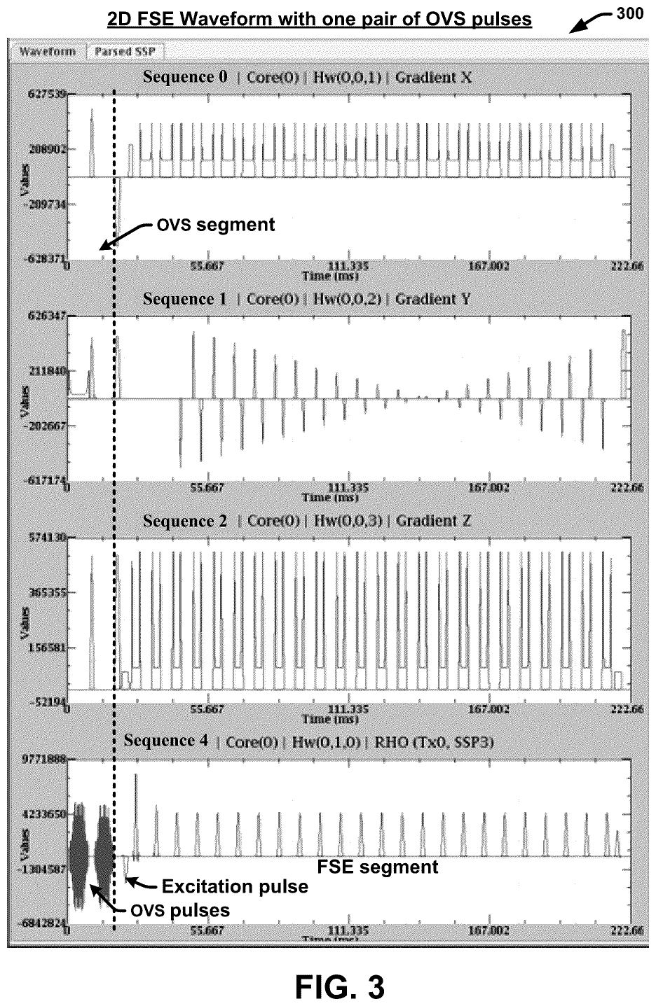

To create an image, the MRI machine 101 employs gradient magnetic fields, which vary in strength across the imaging volume. These gradients encode spatial information into the emitted RF signals, allowing the MRI machine to determine the location of each received RF signal within the body. These gradient magnetic fields are additional magnetic fields superimposed onto the main magnetic field B₀. These gradients vary in strength along the x, y, and z axes of the MRI scanner. Gradient coils within the MRI machine produce these gradient magnetic fields. By controlling the strength and timing of these gradients in combination with controlling the timing, strength and frequency of the RF pulses, spatial encoding is achieved, allowing for the localization of the emitted RF signals from different regions of the body. The information defining the specific strength and timing of the RF pulses and the gradients for a particular imaged slice is referred to as the MR sequence and is typically graphically represented as a waveform (e.g., such as waveform 300, described infra with reference to FIG. 3).

In this regard, MRI machine 101 includes a magnetostatic field magnet unit 104, a gradient coil unit 106, an RF body coil unit 108, one or more local RF coil arrays (112, 114, and 116), an RF port interface 122, a transmit/receive (T/R) switch 124, a data acquisition unit 126, an RF driver unit 128, and a gradient coil driver unit 130. MRI machine 101 also include a table upon which the subject 118 being imaged is positioned. The subject 118 may be moved inside and outside the imaging space 120 by moving the table 110 based on control signals provided by the operating device 102.

The magnetostatic field magnet unit 104 includes, for example, typically an annular superconducting magnet, which is mounted within a toroidal vacuum vessel. The magnet defines a cylindrical space surrounding the subject 118 and generates the constant, primary magnetostatic field B₀. The MRI machine 101 further includes a gradient coil unit 106 that generates the magnetic field gradients, and a radio frequency (RF) system including an RF body coil unit 108 and/or one or more local RF coil arrays 112, 114 and 116, that transmit the RF pulses directed to the tissues within the particular slice of the subject being imaged, and receive the RF signals emitted by the protons during relaxation.

In this regard, based on control signals from the operating device 102, gradient waveforms for performing a prescribed 2D scan are applied to the gradient coil unit 106 by the gradient coil driver unit 130 to produce the magnetic field gradients Gₓ, G_{y} and G_{z} that are used for spatially encoding the RF signals. In particular, the gradient coil unit 106 includes three gradient coil systems, each of which generates a gradient magnetic field which inclines into one of the three spatial axes (e.g., axes x, y and z, perpendicular to each other) of the MRI machine 101, and generates a gradient field in the direction of each axis. The gradient coil driver unit 130 includes three systems of driver circuits (not shown) corresponding to the three gradient coil systems included in the gradient coil unit 106.

For example, generally, the three spatial axes include a z-axis that extends laterally along the length of the subject 120 as positioned on the table 110 within the imaging space 120 (e.g., along the direction of from the subject's head to the subject's feet), an x-axis that extends in the direction planar with the surface of the table 110 (e.g., from the left side to the right side of the subject), and a y-axis that extends perpendicular from the surface of the table 110 (e.g., from the backside to the frontside of the patient 118). The respective magnetic field gradients Gₓ, G_{y} and G_{z} are used to spatially encode the RF signals relative to the three axes or directions. This involves using a first gradient to determine the location of the slice of the subject being imaged (typically relative to the z-axis and thus G_{z}), a second gradient to frequency encode the signals along another axis or direction, referred to as the frequency encoding direction (e.g., either the x-axis or the y-axis), and the third gradient to phase encode the signals along the remaining axis or direction, referred to as the phase encoding direction (e.g., either the x-axis or the y-axis).

In association with acquiring an image of a slice of an anatomical region of the subject 118 as sliced relative to one of the three axes (e.g., typically along the length of and perpendicular to the z-axis), the gradient coil unit 106 applies a gradient field (e.g., G_{z}) in the slice selection direction (or scan direction) of the subject 118 to facilitate selecting the desired slice of the subject 118. This involves using the gradient field generated in the slice selection direction to determine the particular frequency range of one or more RF pulses to be transmitted to the selected slice by the RF system to excite hydrogen nuclei within the portion of the subject 118 corresponding to the position of the slice along the slice selection axis (e.g., typically the z-axis). In association with reconstructing a 2D image from the acquired signal data defined by a 2D array of pixels having dimensions x, y, the frequency encoding gradient is used to determine the signals corresponding to each position along one dimension (e.g., either the x or y dimension) of the image and the phase encoding gradient is used to determine the signals corresponding to each position along the other dimension (e.g., either x or y) of the image. Frequency encoding is achieved using a gradient magnetic field along one axis (usually the x-axis or readout direction). This gradient causes variations in the resonant frequency of the RF signals emitted by the hydrogen nuclei, allowing spatial information to be encoded along that axis. Phase encoding is achieved using a gradient magnetic field along another axis (usually the y-axis or phase encoding direction). This gradient causes variations in the phase of the RF signals emitted by the hydrogen nuclei, allowing additional spatial information to be encoded along that axis. During data acquisition, multiple phase encoding steps are performed to sample the signal along the phase encoding direction. Each phase encoding step corresponds to a different strength or duration of the phase encoding gradient, causing a different phase shift in the emitted RF signals. By acquiring data with different phase encoding steps, a series of lines or “k-space lines” are sampled along the phase-encoding direction. The number of phase encoding steps corresponds to the number of pixels to be included in the reconstructed image along one dimension of the image (e.g., either the x dimension or the y dimension). The number of phase encoding steps also controls the duration of time required to obtain signal data needed to create a 2D image of slice of the body imaged. Accordingly, the phase encoding direction can be selectively chosen to correspond to either the x-axis or the y-axis, depending on the particular region of the body being imaged, whichever requires the fewest number of phase encoding steps to cover the anatomy being imaged along the corresponding direction.

The RF system of MRI machine 101 includes an RF body coil unit 108 and/or one or more local RF coil arrays 112, 114 and 116. Based on control signals from the operating device 102, by the RF driver unit 128, the RF driver unit applies an RF waveform for performing the 2D scan to the RF body coil unit 108 and/or the one or more local coil arrays 112, 114 and 116 to perform the prescribed RF pulse sequence. Responsive/emitted RF signals detected by the RF body coil unit 108 and/or the one or more local coil arrays 112, 114 and 116 are received by the data acquisition unit 126. The RF system includes at least one transmitting RF coil for producing a wide variety of RF pulses used in MRI pulse sequences and at least one receiving coil for receiving the responsive MR signals for relaying to the data acquisition unit 126 (e.g., via the RF port interface 122 and the T/R switch 124). The transmitting RF coil is responsive to the prescribed scan and direction indicated defined in by the prescribed RF waveform to produce one or more RF pulses of the desired frequency, phase and pulse amplitude waveform.

In accordance with MRI system 100, MRI machine 101 includes three local RF coil arrays 112, 114, and 116. The local RF coil arrays are disposed, for example, to enclose the region to be imaged of the subject 118. In the static magnetic field space or imaging space 120 where the main magnetic field B₀ is formed by the magnetostatic field magnet unit 104, the local RF coil arrays 112, 114 and 116 may transmit, based on a control signal from the operating device 102, an initial RF pulse that is an electromagnet wave to the subject 118 and thereby generates a high-frequency magnetic field B₁. This excites a spin of protons in the slice to be imaged of the subject 118. The local RF coil arrays 112, 114 and 116 may also transmit one or more additional refocusing RF pulses depending on the prescribed pulse sequence. The local RF coil arrays receive, as an RF signal, the electromagnetic wave generated when the proton spin returns into alignment with the initial magnetization vector following each refocusing pulse. In one embodiment, the local RF arrays coil may transmit and receive an RF pulse using the same local RF coil. In another embodiment, one or more of the local RF coil arrays may be used for only receiving the MR signals, but not transmitting the RF pulses. One or more of the RF coil arrays 112, 114 and/or 116 may be coupled to the table 110 and moved together with the table.

The RF body coil unit 108 is disposed, for example, to enclose the imaging space 120, and produces RF magnetic field pulses B₁ orthogonal to the main magnetic field B₀ produced by the magnetostatic field magnet unit 104 within the imaging space 120 to excite the nuclei. In contrast to the local RF coil arrays (such as local RF coil arrays 112, 114 and 116), which may be easily disconnected from the MRI machine 101 and replaced with another local RF coil, the RF body coil unit 108 is fixedly attached and connected to the MRI machine 101. Furthermore, whereas local coil arrays can transmit to or receive signals from only a localized region of the subject 118, the RF body coil unit 108 generally has a larger coverage area and can be used to transmit or receive signals to the whole body of the subject 118. Using receive-only RF coil arrays and transmit body coils provides a uniform RF excitation and good image uniformity at the expense of high RF power deposited in the subject. For a transmit-receive RF coil array, the coil array provides the RF excitation to the region of interest and receives the MR signal, thereby decreasing the RF power deposited in the subject. It should be appreciated that the particular use of the local RF coil arrays 112, 114 and 116 and/or the RF body coil unit 108 depends on the imaging application.

The T/R switch 124 can selectively electrically connect (e.g., via the RF port interface 122) the RF body coil unit 108 to the data acquisition unit 126 when operating in receive mode, and to the RF driver unit 128 when operating in transmit mode. Similarly, the T/R switch 124 can selectively electrically connect (e.g., via the RF port interface 122) one or more of the local RF coil arrays 112, 114 and/o 116 to the data acquisition unit 126 when the local RF coil arrays operate in receive mode, and to the RF driver unit 128 when operating in transmit mode. When the local RF coil arrays 112, 114 and/or 116 and the RF body coil unit 108 are both used in a single scan, for example if the local RF coil arrays are configured to receive MR signals and the RF body coil unit 108 is configured to transmit RF signals, then the T/R switch 124 may direct control signals from the RF driver unit 128 to the RF body coil unit 108 via the RF port interface 122 while directing received MR signals from the local RF coil arrays 112, 114 and/or 116 to the data acquisition unit 126. The RF body coil unit 108 may be configured to operate in a transmit-only mode, a receive-only mode, or a transmit-receive mode. The local RF coil arrays 112, 114 and/or 116 may be configured to operate in a transmit-receive mode or a receive-only mode.

The RF driver unit 128 can include a gate modulator, an RF power amplifier, and an RF oscillator (not shown) that are used to drive the RF coil arrays and form a high-frequency magnetic field in the imaging space 120. The RF driver unit 128 modulates, based on a control signal from the controller unit operating device 102 and using the gate modulator, the RF signal received from the RF oscillator into a signal of predetermined timing having a predetermined envelope. The RF signal modulated by the gate modulator may be amplified by the RF power amplifier and then output to the RF coil arrays.

The data acquisition unit 126 includes a preamplifier, a phase detector, and an analog/digital converter used to acquire the responsive RF signals received by the local RF coil arrays 112, 114, and 116 and/or the RF body coil unit 108. In the data acquisition unit 126, the phase detector phase detects, using the output from the RF oscillator of the RF driver unit 128 as a reference signal, the signals received from the RF coil arrays and/or the RF body coil unit 108 and amplified by the preamplifier, and outputs the phase-detected analog magnetic resonance signals to the analog/digital converter for conversion into digital signals. The digital signals thus obtained are output to the operating device 102 for image reconstruction processing thereof.

FIG. 2 presents an example operating device 102 of MRI system 100 that facilitates controlling acquisition of 2D MRI images using a combination of a NPW protocol and an OVS protocol, in accordance with one or more embodiments of the disclosed subject matter. With reference to FIGS. 1 and 2, embodiments of systems (e.g., MRI system 100 and the like) described herein can include one or more machine-executable or computer-executable components embodied within one or more machines (e.g., embodied in one or more computer-readable storage media associated with one or more machines). Such components, when executed by the one or more machines (e.g., processors, computers, computing devices, virtual machines, etc.) can cause the one or more machines to perform the operations described.

For example, operating device 102 includes several machine/computer-executable components 202, including (but not limited to) control component 204, configuration component 206, reconstruction component 216 and rendering component 218. These computer/machine executable components 202 can be stored in (at least one) memory 222 of the operating device 102 which can be coupled to (at least one) processing unit 224 (or processor) for execution thereof. Generally, the control component 204 can control acquisition of a signal data associated with a region of interest (ROI) of an anatomical region of the subject 118 using a using MRI system 100, wherein the controlling comprises employing a combination of an OVS suppression protocol and a NPW protocol with a 2D MRI process. In various embodiments, the defined 2D MRI process can include a 2D FSE process. However, the disclosed OVS and NPW combination techniques can be applied to any 2D MRI process, including standard spine echo process, a TSE process, and others. The reconstruction component 216 can reconstruct an image of the ROI from the acquired signal data in accordance with the acquisition protocols and acquisition parameters employed, and the rendering component 218 can render the image via an electronic display coupled to the operating device 102. In various embodiments, the configuration component 206 can configure (and/or facilitate configuring based in part on user input provided by the operating technician) the specific acquisition parameters that control the acquisition of the signal data in accordance with the 2D MRI process employed and the combination of the OVS and the NPW protocol.

Operating device 102 can also include one or more input/output devices 226 that facilitate receiving user input and/or rendering output data to users in association controlling operations of the MRI machine 101 and generating MR images. For example, the one or more input/output devices 226 can include an electronic display via which a control graphical user interface (GUI) can be presented (e.g., via rendering component 214) to an operating technician of the MRI machine 101 that controls performance of an MRI scan for the subject 118 to obtain one or more 2D images of an anatomical region of interest of the subject 118. Images reconstructed (e.g., via reconstruction component 216) based on signal data acquired from the scanned region of the subject 118 via the MRI machine 101 (e.g., via data acquisition unit 126) may also be rendered (e.g., via rendering component 218) via the control GUI. The input/output devices 226 can also include any suitable input device (e.g., a keyboard, a mouse, a touchscreen, etc.) that enables the operator to provide input via the control GUI that controls operations of the MRI machine 101, including selecting and/or defining the MR pulse sequence and/or acquisition protocols to be applied for the scan, selecting/setting the particular acquisition parameters, selecting/setting the particular slice and/or region of ROI within the slice to be scanned an imaged, and so on.

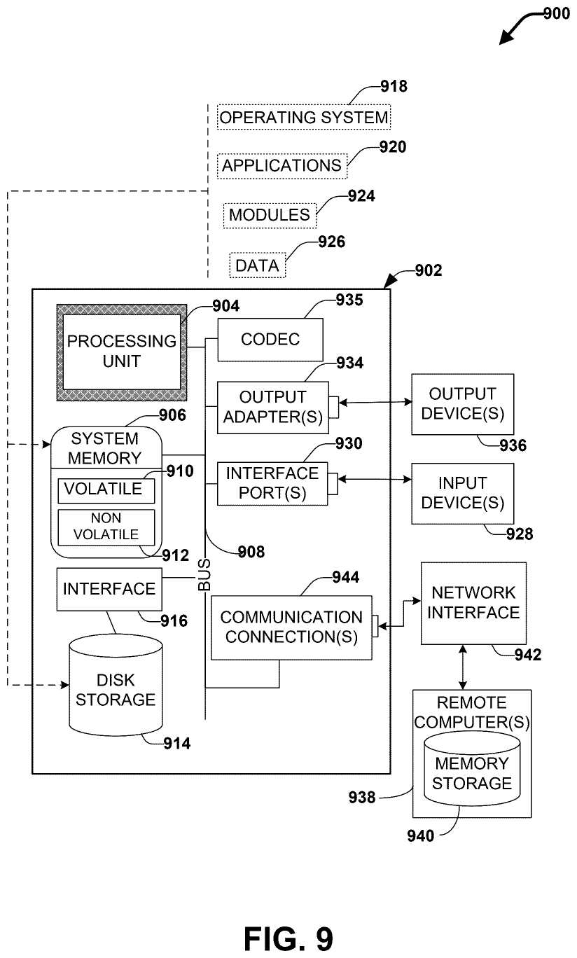

Operating device 102 also includes a system bus 220 that communicatively and operatively couples the memory 222, the processing unit 224, and the input/output devices 226 to one another. Examples of said and memory 222, processing unit 224, input/output devices 226, and other suitable computer or computing-based elements, can be found with reference to FIG. 9 and can be used in connection with implementing system or components shown and described in connection with FIG. 2 and other figures disclosed herein.

In accordance with various embodiments, the control component 204 controls operations of the MRI machine 101 in accordance with instructions provided by the configuration component 206. To this end, the configuration component 206 can determine, define and/or configure (e.g., based in part on operator input received via the control GUI) the particular acquisition protocols and/or acquisition parameters to be applied by the MRI machine 101 for acquiring signal data associated with a ROI of an anatomical region of the subject 118, wherein the anatomical region corresponds to a selected slice or cross-sectional area of the subject from a particular slice selection axis (e.g., as applied for 2D MRI as opposed to 3D MRI, wherein the anatomical region corresponds to a defined volume region). The control component 204 can in turn control acquisition of the signal data by the MRI machine 101 in accordance with the configured acquisition protocols and/or acquisition parameters. For example, the control component 204 can direct (e.g., via one or more control signals communicated by the control component 204 to the data acquisition unit 126, the RF driver unit 128 and the gradient driver unit) the MRI machine 101 to acquire MR signal data from a selected slice (or portion thereof) of an anatomical region of the subject 118 in accordance with a defined 2D MRI process (e.g., FSE or another 2D MRI process) and one or more defined acquisition protocols and/or acquisition parameters for the 2D MRI process configured by the configuration component 206.

In various embodiments, the particular acquisition protocols and/or acquisition parameters configured by the configuration component 206 and applied by the control component 204 can include a combination of a NPW protocol and an OVS protocol in conjunction with a standard 2D MRI process (e.g., FSE or another standard or future 2D MRI process). The reconstruction component 216 can further generate a 2D image of the ROI from the acquired signal data in accordance with the acquisition protocols/parameters employed. To facilitate this end, the configuration component 206 can include (but is not limited to), ROI component 208, OVS component 210, NPW component 212 and optimization component 214.

In various embodiments, ROI component 208 can facilitate defining the ROI of an anatomical region of the subject 118 to be included in a medical image captured by the MRI system 100. The ROI corresponds to desired FOV of the anatomy of the subject 118 to be included in the medical image. For example, in some implementations the ROI can include or correspond to a portion of a selected slice or cross-sectional region of the body, such as a portion of one or more anatomical structures within the selected slice/cross-sectional region. The mechanism via which the ROI component 208 facilitates defining the ROI can vary. For example, in some embodiments, the mechanism via which the ROI component 208 facilitates defining the ROI be based on user input entered via the control GUI defining the 2D rectangular dimensions of the ROI for a selected slice or cross-sectional view of the body. In some implementations of these embodiments, the control GUI can render one or more preliminary images corresponding to the selected slice or cross-sectional region of the body to be scanned, such as one or more low-resolution scout images or the like. With these implementations, the ROI component 208 can facilitate receiving user input defining the 2D rectangular dimensions of the ROI relative to the one or more scout images.

To this end, the disclosed techniques are particularly concerned with minimizing or eliminating wrap-around artifacts. A wrap-around artifact, a form of aliasing, occurs when the anatomic dimensions of the object and/or the tissues of interest within the selected FOV/ROI exceed the selected FOV/ROI. This is often observed in small FOV imaging, such as in association with capturing an MR image of a portion of an organ, tissue, or another type of anatomical structure. In this regard, without performing a compensatory protocol, the portions of the object outside the selected FOV/ROI can be misidentified during image reconstruction in terms of frequency and are folded over into the image from the periphery, creating discontinuities or errors in the resulting image, referred to as wrap-around artifacts (or similar terms). Wrap-around artifacts can distort the image and make it difficult to interpret accurately. Wrap-around artifacts are typically exclusively seen in the phase encoding direction. Thus, conventional NPW techniques involve extending the 1D linear dimension of the signal acquisition FOV beyond the ROI in the phase encoding direction, that is the phase field-of-view (PFOV), while keeping the 1D linear dimension of the signal acquisition in the frequency encoding direction the same.

In various embodiments, to facilitate minimizing or eliminating wrap-around artifacts in scenarios in which the dimensions of one or more anatomical structures included in the selected ROI exceed the ROI in the phase encoding direction, the NPW component 212 can provide a flexible NPW protocol that can be used in association with configuring the acquisition parameters to be applied by the MRI machine 101 during signal acquisition in combination with usage of an OVS protocol. In various embodiments, in accordance with existing NPW protocols and similar protocols (e.g., phase oversampling, or the like), the flexible NPW protocol can control the PFOV and the number of phase-encoding steps. For example, the flexible NPW protocol can increase the PFOV in the phase encoding direction beyond the selected FOV/ROI and the corresponding number of phase encoding steps by the same factor (e.g., so as to maintain the same resolution that would have been achieved without increasing the PFOV). For instance, in accordance with the flexible NPW protocol, the PFOV can be controlled as a function of a the NPW parameter value, which corresponds to a multiplier value via which the linear dimension of the PFOV and the number of phase encoding steps is increased. For example, usage of a NPW parameter value of 2.0 corresponds to doubling the PFOV and the phase encoding steps. Based on application of the NPW protocol and a particular value for the NPW parameter, the signal data acquired by the MRI machine includes signal data covering the entire PFOV. In association generating an image from the acquired signal data in accordance with the NPW protocol and the applied PFOV, the reconstruction component 216 can in turn reconstruct an image from the entirety of the acquired signal data in the PFOV, and then generate a final image of only the ROI by removing or cutting/cropping out the extra pixels outside of the ROI corresponding to the extended PFOV.

However, by combining the NPW protocol with an OVS protocol, the flexible NPW protocol can enable using a smaller PFOV (and thus a smaller number of phase encoding steps) relative to that required by the NPW protocol alone to obtain an image of the ROI without artifacts (or with a desired minimum level of artifacts). For instance, as noted above, in embodiments, the NPW parameter value corresponds to a multiplier value via which the 1D linear dimension of the PFOV and the number of phase encoding steps is increased. For example, a NPW parameter value of 2.0 corresponds to doubling the PFOV and the phase encoding steps. Because the number of phase encoding steps is increased (e.g., doubled in this example), this results in increasing the duration of the signal acquisition time (e.g., doubling the duration in this example). In accordance with a conventional NPW protocol, a NPW parameter value of 2.0 is generally always applied as a default to ensure no or minimal wrap around artifacts are included in the final, reconstructed and cropped image. Thus, a reduced value less than 2.0 can provide significant scan time savings as applied to acquire several 2D images across a designated volume region during an MRI scan.

To this end, in accordance with the disclosed techniques, the NPW parameter or factor value that controls the linear dimension of the PFOV is flexible and can be decreased without increasing wrap-around artifacts as a result of adding an OVS protocol to the signal acquisition, thereby decreasing the signal acquisition time. In other words, by decreasing the NPW parameter value, this decreases the PFOV and the number of phase encoding steps and thus results in decreasing the duration of time required to acquire the signal data needed to construct the image of the ROI. In addition, in combination with the OVS protocol, the NPW parameter value be selectively decreased or increased as needed to balance minimizing wrap around artifacts and scan time depending on the characteristics (e.g., dimensions, tissue type, size, position, etc.) of the anatomical structure or structures included in the ROI and the PFOV.

In this regard, the OVS component 210 can facilitate applying an OVS protocol in addition to the flexible NPW protocol in association with acquiring the signal data by the MRI machine 101 to minimize scan time associated with usage of conventional NPW techniques. The OVS protocol can comprise employing an MRI pulse sequence that comprises one or more radio RF pulses configured to suppress emitted (and thus acquired) RF signals from tissues in one or more outer volume regions of the imaged anatomical region outside the ROI in the phase encoding direction. These suppression pulses are designed to null or reduce the magnetization of protons in the outer volume regions while preserving the magnetization of protons within the ROI. In various embodiments, the one or more OVS pulses correspond to cosine modulated pulses configured to suppress signals on both sides of the PFOV in the phase encoding direction. In some implementations, a single RF suppression pulse can be applied. In other implementations, a pair of two suppression pulses can be applied. Still in other embodiments, three or more suppression pulses can be applied.

To this end, based on the ROI, the OVS component 210 can determine or facilitate defining (e.g., via user input) the spatial position and dimensions of one or more outer volume regions outside the ROI in the phase encoding direction. Based on the position of the one or more outer volume regions and the slice selection gradient applied, the OVS component 210 can determine the appropriate frequency of the one or more suppression pulses that results in targeting the tissues in the outer volume regions. In accordance with the OVS protocol, these one or more RF suppression pulses are applied to the selected slice or cross-sectional region of the anatomy being imaged prior to the initial excitation pulse of the MRI pulse sequence employed (e.g., an FSE sequence or the like). Thus, in association with configuring the MRI pulse sequence for acquiring signal data associated with the ROI to construct an image of the ROI, the OVS component 210 can integrate the one or more RF suppression pulses into the pulse sequence prior to the initial excitation pulse and the control component 204 can control acquisition of the signal data in accordance with the configured pulse sequence, as illustrated in FIG. 3.

FIG. 3 presents an example 2D FSE waveform 300 with one pair of OVS pulses, in accordance with one or more embodiments of the disclosed subject matter. With reference to FIG. 3 in view of FIGS. 1 and 2, waveform 300 corresponds to an example MRI sequence that can be configured (e.g., via the configuration component 206) and applied by the MRI machine 101 as directed by the control component 204 to acquire signal data associated with a slice or cross-sectional region of the subject 118, wherein the slice includes a defined ROI with one or more anatomical objects with dimensions that extend past the ROI and into one or more outer volume regions of in the phase encoding direction. Waveform 300 is separated into four separate components, respectively corresponding to the three different gradient waveforms, gradient Gₓ/sequence 0, gradient G_{y}/sequence 1, and gradient G_{z}/sequence 2, and the RF pulse sequence waveform, sequence 4. In this example, sequence 2 corresponds to the slice selection gradient, sequence 1 corresponds to the phase encoding gradient, and sequence 0 corresponds to the frequency encoding gradient.

As illustrated in the RF pulse sequence, sequence 4, prior to the excitation pulse, the OVS segment includes a pair of OVS pulses. These OVS pulses correspond to RF pulses configured to suppress RF signals emitted by tissues included in one or more outer volume regions outside the ROI in the phase encoding direction within the anatomical region of the subject 118 scanned (e.g., within the selected slice). In this regard, during readout, the portion of the detected signal data corresponding to the tissues in the outer volume regions is suppressed as a result of application of the OVS pulses prior to the excitation pulse. In various embodiments, two OVS pulses of different thickness and locations can be used as opposed to a single OVS pulse to make the resulting spins of the protons in the tissues in the outer volume regions more robust against suppression by the main magnetic field B₀. The thickness and locations are automatically determined using empirical calculation by considering B0 field distortion in the area being scanned.

Waveform 300 corresponds to an MR sequence used to acquire one repetition of signal data associated with the slice or cross-sectional region of the subject 118 being scanned. It should be appreciated that the MR sequence represented by waveform 300 can be repeated a defined number of repetition times to acquire the signal data accounting for a defined number of phase steps to create an image of a defined resolution covering the defined PFOV, in accordance with conventional FSE techniques. For instance, in this example, the FSE segment shown in sequence 4 has an echo train length of 16, and thus to obtain an image having a resolution of 256×256 pixels, waveform 300 can be repeated 16 times.

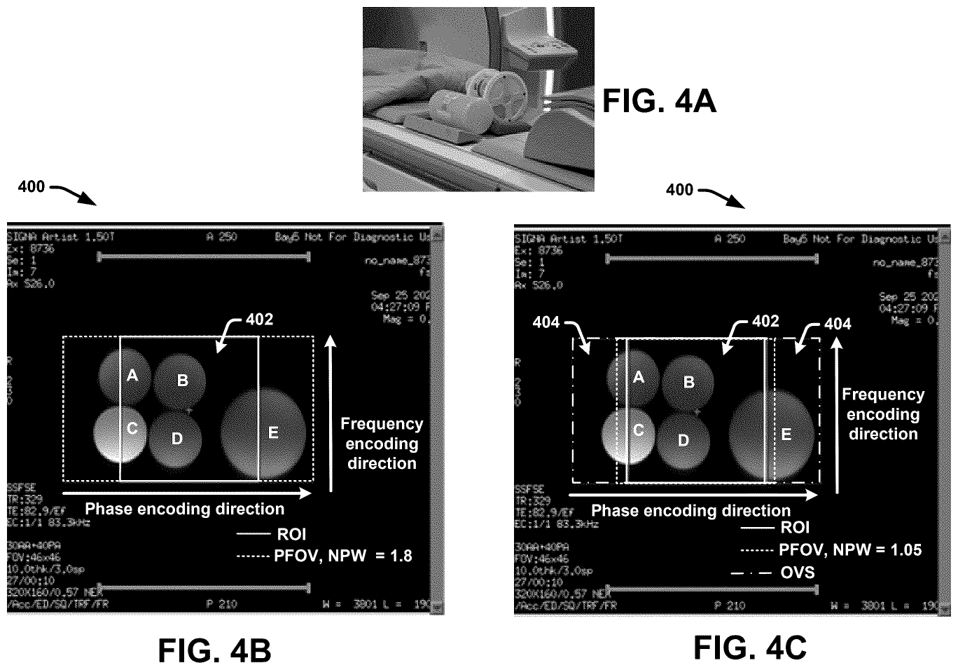

Thus, in accordance with the disclosed techniques, based on employing the combination of the OVS protocol and the NPW in conjunction with a 2D MRI process to acquire signal data associated with a ROI of the subject 118 in scenarios in which the dimension of the anatomical structure or structures in the ROI extend outside the ROI in the phase encoding direction, the resulting final reconstructed image of only the ROI comprises a defined image quality of having no wrap around artifacts or an amount of the wrap around artifacts being less than a defined amount. In addition, the duration of the acquisition of the signal data is reduced relative to another acquisition duration of a variation of the 2D MRI process employable to generate a corresponding image of the ROI with the defined image quality, the variation comprising the NPW protocol and excluding the OVS protocol. In this regard, based on using the combination of the NPW protocol and the OVS protocol, the NPW parameter value applied to control the PFOV and the number of phase encoding steps can be reduced in comparison to the value of the NPW parameter required to achieve the same image quality using the 2D MRI process with the NPW protocol without the OVS protocol, with all other acquisition parameters and imaging reconstruction processing being the same. In this regard, in accordance with the disclosed techniques, varying the value for the NPW parameter controls the amount of the wrap-around artifacts in the final image and the duration of the acquisition time, and wherein the FOVP and the duration increases as the value increases, as illustrated in FIGS. 4A-6C.

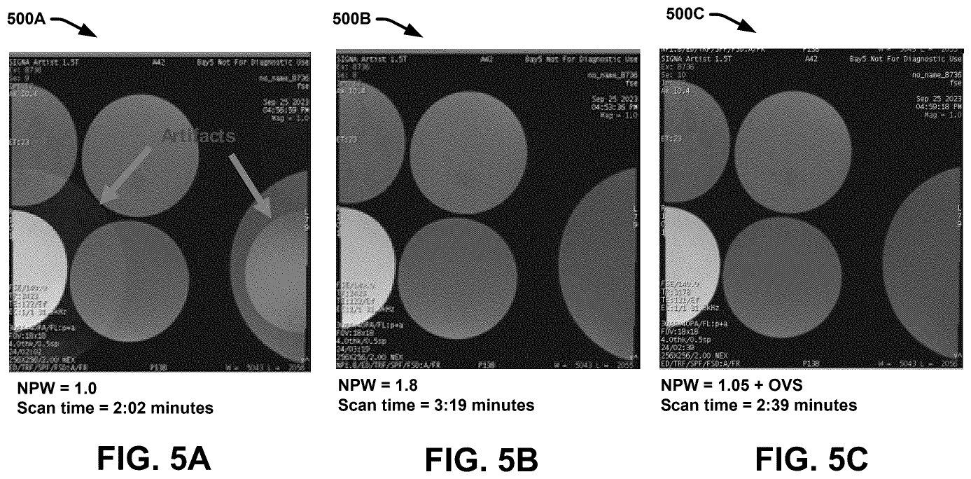

FIG. 4A presents an image of phantom objects in an example MRI scanner corresponding to MRI machine 101 used to create example phantom images shown in FIGS. 4B-5C. In this example, five phantom objects were used, respectively indicated as objects A, B, C, D and E. The phantom objects included 5 cylindrical bottles filled with different substances.

FIGS. 4B and 4C illustrate an example scout phantom image 400 created via the MRI scanner using the object configuration shown in FIG. 4A. With reference to FIGS. 1-4C, in various embodiments, scout phantom image 400 corresponds to an example scout image that can be rendered via the operating device 102 (e.g., via rendering component 218 and a suitable display) to facilitate receiving user input in association with configuring the ROI and defining the acquisition parameters for obtaining high resolution signal data of the objects needed to reconstruct a high resolution 2D image of a cross-section of the scanned object.

In FIGS. 4B and 4C, region 402 corresponds to the ROI or the desired FOV of the objects to be included in the high-resolution image of the same. The frequence encoding direction and the phase encoding direction to be applied for the signal acquisition are indicated with respect to the scout phantom image 400. FIG. 4B illustrates defining/configuring the PFOV in accordance with a NPW protocol only. FIG. 4C illustrates defining/configuring the PFOV in accordance with combination including the NPW protocol and the OVS protocol. As shown in FIGS. 4B and 4C, the ROI (region 402), includes the entirety of objects B and D, and some portions of objects A, C and E. The remaining portions of objects A, C and E extend outside the ROI (region 402) along the phase encoding direction. The dashed line in FIGS. 4B and 4C corresponds to boundary of the PFOV created as a result of applying the NPW parameter values of 1.8 and 1.05, respectively, in association with configuring the acquisition of the signal data in accordance with the NPW protocol. In this example, the NPW parameter corresponds to a multiplier value via which the 1D linear dimensions of the of the RIO (region 402) are increased in the phase encoding direction to defined the PFOV. The number of phase encoding steps is also proportionally increased via the same multiplier value.

As shown in FIG. 4B, the NPW factor of 1.8 results in increasing the PFOV along the phase encoding direction on opposite sides of the ROI to include the entirety of the portions of objects A, C and E that extend outside the ROI, region 402. On the contrary, as shown in FIG. 4C, the NPW factor of 1.05 results in only slightly increasing the PFOV along the phase encoding direction on opposite sides of the ROI. However, based on configuring the OVS protocol in combination with the NPW, the OVS component 210 defines OVS regions 404 on opposite sides of the PFOV in the phase encoding direction for suppressing signals emitted by the remaining portions of objects A, C and E included in the OVS regions. Based on the positions of the OVS regions 404, the OVS component 210 can configure one or more OVS pulses (RF pulses) to be transmitted to the OVS regions prior to the excitation pulse of the MR sequence to be applied for capturing the high-resolution signal data. As described above, these OVS pulses result in suppressing signals emitted from the remaining portions of objects A, C and E included in the OVS regions.

FIGS. 5A-5C illustrate different high resolution phantom images corresponding to the scout image 400. With reference to FIGS. 5A-5C, in view of FIGS. 1-4C, each of the high-resolution phantom images 500A, 500B and 500C were acquired via an MRI system corresponding to system 100 using a 2D FSE process and the configuration of the phantom objects as acquired in scout phantom image 400. FIGS. 5A and 5B illustrate images 500A and 500B resulting from using different NPW parameter values and a NPW protocol only. In particular, FIG. 5B illustrates a resulting image obtained in accordance with the configuration shown in FIG. 4B, wherein the value of the NPW parameter used was 1.8. FIG. 5A illustrates the resulting image obtained in accordance with the configuration shown in FIG. 4B, yet wherein the NPW factor used was 1.0, which effectively corresponds to no application of the NPW protocol and a PFOV corresponding to the 1D linear dimension of the ROI (region 302) in the phase encoding direction. As can be seen via comparison of image 500A and image 500B, image 500A includes wrap-around artifacts while image 500B does not. Thus, the NPW factor of 1.8 was sufficient to counteract the wrap-around artifacts attributed to the portions of objects A, C and E extending beyond the ROI in the phase encoding direction. Notably however, the scan time needed to acquire the signal data to construct image 500B with the extended PFOV at 3.19 minutes was significantly longer than the scan time needed to acquire the signal data to construct image 500A without the extended PFOV (which was 2.02 minutes).

FIG. 5C illustrates a resulting image 500C obtained in accordance with the configuration shown in FIG. 4C, wherein the value of the NPW parameter used was 1.05 and wherein OVS was also applied. As can be seen via comparison of images 500C and 500B, wrap-around artifacts are excluded from both images. Thus, the combination of the OVS protocol and the NPW protocol with the significantly lower NPW parameter value of 1.05 (and thus a significantly smaller PFOV and lower number of phase encoding steps) proves effective at eliminating wrap-around artifacts. More importantly, the scan time needed to acquire the signal data to construct image 500C, at 2.39 minutes, was significantly shorter than the scan time needed to acquire the signal data to construct image 500B.

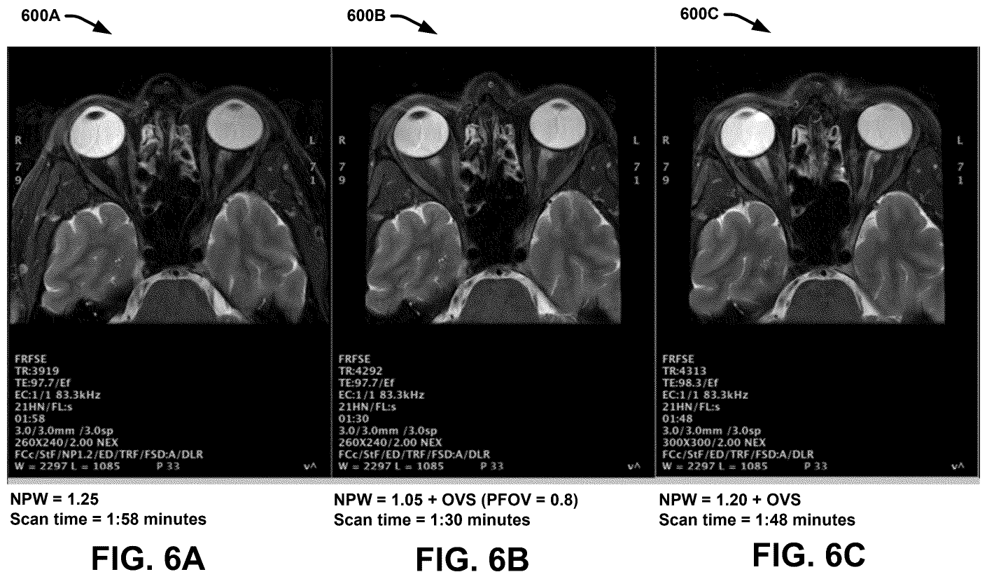

FIGS. 6A-6C present different versions of orbit MRI images resulting from different acquisition parameters, in accordance with one or more embodiments of the disclosed subject matter. With reference to FIGS. 1-6C, the MRI images shown in FIGS. 6A-6C were respectively constructed from signal data captured via an MRI system corresponding to MRI system 100 using a 2D FSE imaging process. Each of the images 600A, 600B and 600C were captured using the same acquisition parameters for the 2D FSE processes despite the differences noted below. In this regard, each of images 600A, 600B and 600C were captured from the coronal perspective such that the slice selection direction corresponds to a linear position along the y-axis of the MRI machine 101 from a FOV including only the frontal portion of the subject's head, and setting the x-axis as the phase encoding direction. To this end, each of images 600A, 600B and 600C do not include wrap around artifacts, yet the acquisition times are notably different owing to usage of the NPW protocol only (for image 600A) and usage of a combination of the NPW protocol and the OVS protocol for images 600B and 600C.

In this regard, for image 600A, only the NPW protocol was used, with a NPW parameter value of 1:25, which resulted in a total scan time of 1:58 minutes. On the other hand, for image 600B the signal data was acquired using the combination of the OVS protocol and the NPW protocol, with a lower NPW parameter value of 1:05, which significantly reduced the scan time relative to that employed for image 600B, from 1:58 minutes to only 1:30 minutes, while still ensuring no wrap around artifacts. Image 600C demonstrates how increasing the NPW in combination with OVS impacts the scan time and the resulting image quality. In this regard, image 600C was acquired using substantially the same acquisition parameters as image 600B, yet with a higher NPW factor of 1.2 in combination with the OVS protocol. As can be seen via comparison of image 600B and 600C, the higher NPW factor did not substantially change the resulting image quality yet added to the acquisition time, thus demonstrating that further increasing the NPW factor in combination with the OVS protocol, is not needed to achieve a high-quality image without wrap around artifacts.

In various embodiments, the in association with using the combination of the NPW protocol and the OVS protocol, the OVS component can 210 can control the OVS FOV in the phase encoding direction, that is the spatial 1D dimensions of the OVS regions in the phase encoding direction, based on the NPW parameter value applied, which can be flexible and selectively increased or decreased as needed based on balancing time constraints for the scan and the amount of wrap around artifacts considered acceptable for the scan (e.g., based on the anatomical region scanned, the preferences of the clinician that prescribed the scan, and so on). For example, using a NPW parameter value of 1.0 (which effectively corresponds to no usage of the NPW protocol as the PFOV in such case corresponds to the length of the ROI in the phase encoding direction) with OVS provides the maximum scan time benefit, however one or more edges of the resulting image may have some wrap around artifacts due to in-field homogeneity. On the other hand, in accordance with the example shown in FIG. 6B, a NPW parameter value greater than 1.05 was not needed in order to achieve an image (e.g., image 600B) without wrap-around artifacts when combined with OVS. In various embodiments, based on combining the NPW protocol with the OVS protocol, the NPW component 212 can control the NPW parameter value applicable for a given slice/cross-sectional view and selected ROI based on the scan perspective and the known characteristics of the anatomical structures associated with the ROI and the scan perspective. In some implementations of these embodiments, the NPW component 212 can restrict the NPW parameter value to be a value within a defined range, such as between 1.04 and 1.9. However, in other embodiments, OVS can be also used with a NPW parameter values less than or equal to 1.04 and greater than or equal to 1.9 to allow flexibility to manage image quality and scan time.

In this regard, in some embodiments, the NPW parameter value can be selected by the operating technician in association with configuring the acquisition parameters for the scan via the control GUI. With these embodiments, the operating technician can choose/select a preferred NPW parameter value based that satisfies a desired time constraint for the scan. In other implementations, the NPW component 212 can automatically determine/select a NPW parameter value that satisfies a defined time constraint for the scan. In either of these embodiments, based on the selected NPW parameter value, the OVS component 210 can determine/define the OVS FOV and configure the OVS pulses accordingly based on the ROI and the PFOV resulting from the selected NPW parameter value. For example, in implementations in which the ROI comprises a portion of one or more target anatomical objects having a total length that extends in the phase encoding direction outside the ROI, the NPW component 212 (and/or the operating technician) can select a NPW parameter value that results in the PFOV being less than the total length of the target anatomical object in the phase encoding direction, (as exemplified in FIG. 4C). The OVS component 210 can then determine the spatial position/dimension of the one or more volume regions in the phase encoding direction based on the ROI, the total length of the target anatomical object in the phase encoding direction, and the NPW parameter value. For example, the OVS component 210 can determine the spatial dimensions of the OVS regions in the phase encoding direction relative to the PFOV boundary based on the total length of the target anatomical object such that the OVS regions include the extended portion or portions of the target anatomical object that extend past the PFOV boundary in the phase encoding direction.

For example, as shown in FIG. 4C. target anatomical objects A, C and E respectively have lengths in the phase encoding direction that extend outside the ROI (region 402). In addition, the selected NPW parameter of 1.05 established a PFOV (defined by the dashed line) that is less than the total length defined by the lateral edges of objects A, C and E in the phase encoding direction. In accordance with this example, based on the PFOV boundary (e.g., the dashed line) in the phase encoding direction, the OVS component 210 can define the spatial positions and dimensions the OVS regions 404 relative to the PFOV boundary such that the OVS regions encompass the entirety of the portions of the objects A, C and E extending beyond the PFOV boundary in the phase encoding direction. In this regard, in implementations in which the extended portion or portions of the object or objects in the phase encoding direction do not extend the entire length of the selected slice/cross-sectional region of the region of the subject to be scanned in the phase encoding direction, the OVS region or regions can be less than the entire length of the selected slice/cross-sectional region of the region of the subject to be scanned in the phase encoding direction.

Additionally, or alternatively, in association with using the combination of the NPW protocol and the OVS protocol, the optimization component 214 can determine or infer the particular parameter values applied for each protocol based in accordance with defined optimization criteria, the defined optimization criteria comprising balancing minimizing a duration of the acquisition of the signal data and minimizing an amount of fold over artifacts included in the image. For example, the optimization component 214 can determine the optimal NPW parameter value (or PFOV) and the optimal OVS regions based on the selected slice of the subject 118 to be scanned, the anatomical structures included in the slice, the selected ROI within the slice, and characteristics of the one or more anatomical structures included in the ROI and outside the ROI in the phase encoding direction. The characteristics of the one or more anatomical structures can include the total length of the anatomical structure included in the imaged slice in the phase encoding direction as well as the material composition of the one or more anatomical structures. In addition, the optimization component 214 can determine or infer the optimal NPW parameter value and the optimal OVS regions based on a time constraint for the scan and an amount of wrap around artifacts considered acceptable for the scan (e.g., based on the anatomical region scanned, the preferences of the clinician that prescribed the scan, and so on). In some implementations of these embodiments, the optimization component 214 can employ artificial intelligence to facilitate inferring the optimal NPW parameter value and the optimal OVS regions for a given slice or set/series of slices to be acquired for the subject during the scan. In some embodiments, the optimization component 214 can recommend the optimal NPW parameter value and the optimal OVS regions for the scan to the operating technician which in turn can select to apply them or edit them as desired. In other embodiments, the configuration component 206 can automatically apply the optimal NPW parameter value and the optimal OVS regions for the scan.

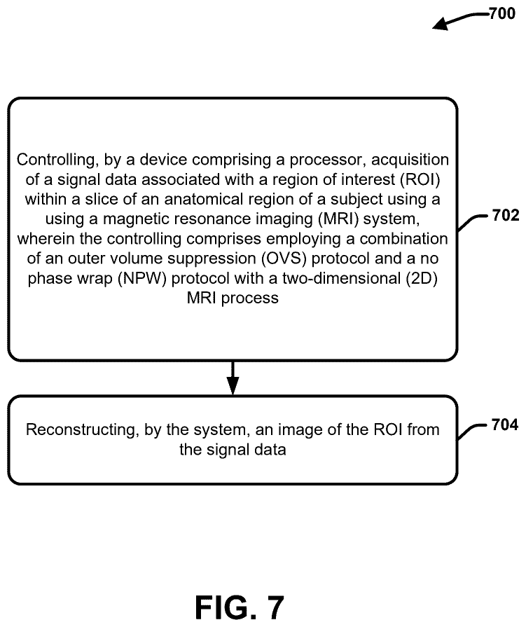

FIG. 7 presents a high-level flow diagram of an example computer-implemented method 700 for performing a 2D MRI process using a combination of an OVS protocol and a NPW protocol, in accordance with one or more embodiments of the disclosed subject matter. Method 700 comprises, at 702 controlling (e.g., via control component 204), by a device comprising a processor (e.g., operating device 102), acquisition of a signal data associated with a region of interest (ROI) within a slice of an anatomical region of a subject using a using a magnetic resonance imaging (MRI) system (e.g., MRI system 100), wherein the controlling comprises employing a combination of an OVS protocol and a NPW protocol with a 2D MRI process. At 702, method 700 further comprises, reconstructing, by the device, an image of the ROI from the signal data (e.g., via reconstruction component 216).

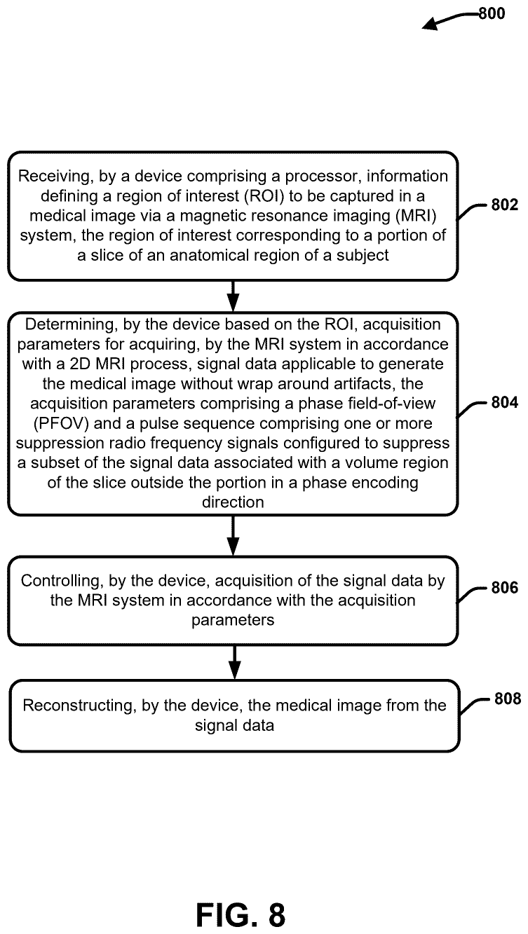

FIG. 8 presents a high-level flow diagram of another example computer-implemented method 800 for performing a 2D MRI process using a combination of an OVS protocol and a NPW protocol, in accordance with one or more embodiments of the disclosed subject matter. Method 800 comprises, at 802 controlling receiving (e.g., via ROI component 208), by a device comprising a processor (e.g., operating device 102), information defining a ROI to be captured in a medical image via a magnetic resonance imaging (MRI) system (e.g., MRI system 100), the region of interest corresponding to a portion of a slice of an anatomical region of a subject. At 804, method 800 comprises determining (e.g., via configuration component 206), by the device based on the ROI, acquisition parameters for acquiring, by the MRI system in accordance with a 2D magnetic resonance imaging process, signal data applicable to generate the medical image without wrap around artifacts, the acquisition parameters comprising a PFOV and a pulse sequence comprising one or more suppression RF signals configured to suppress a subset of the signal data associated with a volume region of the slice outside the portion in a phase encoding direction. At 806, method 800 comprises controlling, by the device (e.g., via control component 204), acquisition of the signal data by the MRI system in accordance with the acquisition parameters. At 808, method 800 comprises reconstructing, by the device, the medical image from the signal data (e.g., via reconstruction component 216).

One or more embodiments can be a system, a method, and/or a computer program product at any possible technical detail level of integration. The computer program product can include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, procedural programming languages, such as the “C” programming language or similar programming languages, and machine-learning programming languages such as like CUDA, Python, Tensorflow, PyTorch, and the like. The computer readable program instructions can execute entirely on the user's computer, partly on the user's computer, as a stand-alone software package, partly on the user's computer and partly on a remote computer or entirely on the remote computer or server using suitable processing hardware. In the latter scenario, the remote computer can be connected to the user's computer through any type of network, including a local area network (LAN) or a wide area network (WAN), or the connection can be made to an external computer (for example, through the Internet using an Internet Service Provider). In various embodiments involving machine-learning programming instructions, the processing hardware can include one or more graphics processing units (GPUs), central processing units (CPUs), and the like. For example, one or more of the disclosed deep-learning models (e.g., the segmentation models, the reconstruction model 118, and/or combinations thereof) may be written in a suitable machine-learning programming language and executed via one or more GPUs, CPUs or combinations thereof. In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It can be understood that each block of the flowchart illustrations and/or block diagrams, and combinations of blocks in the flowchart illustrations and/or block diagrams, can be implemented by computer readable program instructions.

These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions can also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession may, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

In connection with FIG. 9, the systems and processes described below can be embodied within hardware, such as a single integrated circuit (IC) chip, multiple ICs, an application specific integrated circuit (ASIC), or the like. Further, the order in which some or all of the process blocks appear in each process should not be deemed limiting. Rather, it should be understood that some of the process blocks can be executed in a variety of orders, not all of which can be explicitly illustrated herein.

With reference to FIG. 9, an example environment 900 for implementing various aspects of the claimed subject matter includes a computer 902. The computer 902 includes a processing unit 904, a system memory 906, a codec 935, and a system bus 908. The system bus 908 couples system components including, but not limited to, the system memory 906 to the processing unit 904. The processing unit 904 can be any of various available processors. Dual microprocessors, one or more GPUs, CPUs, and other multiprocessor architectures also can be employed as the processing unit 904.

The system bus 908 can be any of several types of bus structure(s) including the memory bus or memory controller, a peripheral bus or external bus, or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Personal Computer Memory Card International Association bus (PCMCIA), Firewire (IEEE 994), and Small Computer Systems Interface (SCSI).

The system memory 906 includes volatile memory 910 and non-volatile memory 912, which can employ one or more of the disclosed memory architectures, in various embodiments. The basic input/output system (BIOS), containing the basic routines to transfer information between elements within the computer 902, such as during start-up, is stored in non-volatile memory 912. In addition, according to present innovations, codec 935 can include at least one of an encoder or decoder, wherein the at least one of an encoder or decoder can consist of hardware, software, or a combination of hardware and software. Although, codec 935 is depicted as a separate component, codec 935 can be contained within non-volatile memory 912. By way of illustration, and not limitation, non-volatile memory 912 can include read only memory (ROM), programmable ROM (PROM), electrically programmable ROM (EPROM), electrically erasable programmable ROM (EEPROM), Flash memory, 3D Flash memory, or resistive memory such as resistive random access memory (RRAM). Non-volatile memory 912 can employ one or more of the disclosed memory devices, in at least some embodiments. Moreover, non-volatile memory 912 can be computer memory (e.g., physically integrated with computer 902 or a mainboard thereof), or removable memory. Examples of suitable removable memory with which disclosed embodiments can be implemented can include a secure digital (SD) card, a compact Flash (CF) card, a universal serial bus (USB) memory stick, or the like. Volatile memory 910 includes random access memory (RAM), which acts as external cache memory, and can also employ one or more disclosed memory devices in various embodiments. By way of illustration and not limitation, RAM is available in many forms such as static RAM (SRAM), dynamic RAM (DRAM), synchronous DRAM (SDRAM), double data rate SDRAM (DDR SDRAM), and enhanced SDRAM (ESDRAM) and so forth.

Computer 902 can also include removable/non-removable, volatile/non-volatile computer storage medium. FIG. 9 illustrates, for example, disk storage 914. Disk storage 914 includes, but is not limited to, devices like a magnetic disk drive, solid state disk (SSD), flash memory card, or memory stick. In addition, disk storage 914 can include storage medium separately or in combination with other storage medium including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage 914 to the system bus 908, a removable or non-removable interface is typically used, such as interface 916. It is appreciated that disk storage 914 can store information related to a user. Such information might be stored at or provided to a server or to an application running on a user device. In one embodiment, the user can be notified (e.g., by way of output device(s) 936) of the types of information that are stored to disk storage 914 or transmitted to the server or application. The user can be provided the opportunity to opt-in or opt-out of having such information collected or shared with the server or application (e.g., by way of input from input device(s) 928).

It is to be appreciated that FIG. 9 describes software that acts as an intermediary between users and the basic computer resources described in the suitable operating environment 900. Such software includes an operating system 918. Operating system 918, which can be stored on disk storage 914, acts to control and allocate resources of the computer 902. Applications 920 take advantage of the management of resources by operating system 918 through program modules 924, and program data 926, such as the boot/shutdown transaction table and the like, stored either in system memory 906 or on disk storage 914. It is to be appreciated that the claimed subject matter can be implemented with various operating systems or combinations of operating systems.

A user enters commands or information into the computer 902 through input device(s) 928. Input devices 928 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 904 through the system bus 908 via interface port(s) 930. Interface port(s) 930 include, for example, a serial port, a parallel port, a game port, and a universal serial bus (USB). Output device(s) 936 use some of the same type of ports as input device(s) 928. Thus, for example, a USB port can be used to provide input to computer 902 and to output information from computer 902 to an output device 936. Output adapter 934 is provided to illustrate that there are some output devices 936 like monitors, speakers, and printers, among other output devices 936, which require special adapters. The output adapters 934 include, by way of illustration and not limitation, video and sound cards that provide a means of connection between the output device 936 and the system bus 908. It should be noted that other devices or systems of devices provide both input and output capabilities such as remote computer(s) 938.

Computer 902 can operate in a networked environment using logical connections to one or more remote computers, such as remote computer(s) 938. The remote computer(s) 938 can be a personal computer, a server, a router, a network PC, a workstation, a microprocessor based appliance, a peer device, a smart phone, a tablet, or other network node, and typically includes many of the elements described relative to computer 902. For purposes of brevity, only a memory storage device 940 is illustrated with remote computer(s) 938. Remote computer(s) 938 is logically connected to computer 902 through a network interface 942 and then connected via communication connection(s) 944. Network interface 942 encompasses wire or wireless communication networks such as local-area networks (LAN) and wide-area networks (WAN) and cellular networks. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL).

Communication connection(s) 944 refers to the hardware/software employed to connect the network interface 942 to the bus 908. While communication connection 944 is shown for illustrative clarity inside computer 902, it can also be external to computer 902. The hardware/software necessary for connection to the network interface 942 includes, for exemplary purposes only, internal and external technologies such as, modems including regular telephone grade modems, cable modems and DSL modems, ISDN adapters, and wired and wireless Ethernet cards, hubs, and routers.

While the subject matter has been described above in the general context of computer-executable instructions of a computer program product that runs on a computer and/or computers, those skilled in the art will recognize that this disclosure also can or can be implemented in combination with other program modules. Generally, program modules include routines, programs, components, data structures, etc. that perform particular tasks and/or implement particular abstract data types. Moreover, those skilled in the art will appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments where tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to and/or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration and are intended to be non-limiting. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations can be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
controlling, by a device comprising a processor, acquisition of a signal data associated with a region of interest (ROI) within an anatomical region of a subject using a using a magnetic resonance imaging (MRI) system, wherein the controlling comprises employing a combination of an outer volume suppression (OVS) protocol and a no phase wrap (NPW) protocol with a two-dimensional (2D) MRI process; and
reconstructing, by the device, an image of the ROI from the signal data.

2. The method of claim 1, wherein based on employing the combination, the image comprises a defined image quality and a duration of the acquisition of the signal data is reduced relative to another acquisition duration of a variation of the 2D MRI process employable to generate a corresponding image of the ROI with the defined image quality, the variation comprising the NPW protocol and excluding the OVS protocol.

3. The method of claim 2, wherein the NPW protocol comprises applying a NPW parameter that controls a phase field-of-view (PFOV) of the signal data in a phase encoding direction of the 2D MRI process, and wherein the employing comprises employing a reduced value for the NWF parameter as a result of the employing the combination relative to another value for the NPW parameter employable to generate the corresponding image of the ROI with the defined image quality using the variation of the 2D MRI process.

4. The method of claim 3, wherein the defined image quality comprises absence of wrap-around artifacts or an amount of the wrap-around artifacts being less than a defined amount.

5. The method of claim 3, wherein the defined image quality comprises an amount of wrap-around artifacts being less than a defined amount, wherein the reduced value is variable, wherein varying the reduced value controls the amount of the wrap-around artifacts and the duration, and wherein the FOV_{P} and the duration increases as the reduced value increases.

6. The method of claim 1, wherein the NPW protocol comprises applying a NPW parameter value that controls a phase field-of-view (PFOV) of the signal data in a phase encoding direction of the 2D MRI process, and wherein the OVS protocol comprises employing a pulse sequence that comprises one or two radio frequency (RF) pulses configured to suppress magnetic resonance signals in one or more volume regions of the anatomical region outside the ROI in the phase encoding direction.

7. The method of claim 6, wherein a value of the NPW parameter is variable, and wherein the PFOV and a duration of the acquisition of the signal data increases as the value increases.

8. The method of claim 6, wherein the ROI corresponds to a portion of a target anatomical object, and wherein the employing the combination comprises:
determining, by the device, the NPW parameter value, and a spatial position of the one or more volume regions in the phase encoding direction based on the ROI, a total length of the target anatomical object in the phase encoding direction, and in accordance with defined optimization criteria, the defined optimization criteria comprising balancing minimizing a duration of the acquisition of the signal data and minimizing an amount of wrap-around artifacts included in the image.

9. The method of claim 6, wherein the ROI corresponds to a portion of a target anatomical object, and wherein the employing the combination comprises:
selecting, by the device, a NPW parameter value that corresponds to the PFOV being less than a total length of the target anatomical object in the phase encoding direction; and
determining, by the device, a spatial position of the one or more volume regions in the phase encoding direction based on the ROI, the total length of the target anatomical object in the phase encoding direction, and the NPW parameter value.

10. The method of claim 1, wherein the 2D MRI process is selected from the group consisting of: a spin echo process, a fast spin echo process, and a turbo spin echo process.

11. A magnetic resonance imaging (MRI) system, comprising:
at least one memory that stores computer-executable components; and
at least one processor that executes the computer-executable components stored in the at least one memory, wherein the computer-executable components comprise:
a control component that controls acquisition of a signal data associated with a region of interest (ROI) within an anatomical region of a subject via the magnetic MRI system using a combination of an outer volume suppression (OVS) protocol and a no phase wrap (NPW) protocol with a two-dimensional (2D) MRI process; and
a reconstruction component that generates an image of the ROI from the signal data.

12. The MRI system of claim 11, wherein based on using the combination with the 2D MRI process, the image comprises a defined image quality and a duration of the acquisition of the signal data is reduced relative to another acquisition duration of a variation of the 2D MRI process employable to generate a corresponding image of the ROI with the defined image quality, the variation comprising the NPW protocol and excluding the OVS protocol.

13. The MRI system of claim 12, wherein the NPW protocol comprises applying a NPW parameter that controls a phase field-of-view (PFOV) of the signal data in a phase encoding direction of the 2D MRI process, and wherein the control component employs a reduced value for the NPW parameter as a result of the employing the combination relative to another value for the NPW parameter employable to generate the corresponding image of the ROI with the defined image quality using the variation of the 2D MRI process.

14. The MRI system of claim 13, wherein the defined image quality comprises an amount of wrap-around artifacts being less than a defined amount, wherein the reduced value is variable, wherein varying the reduced value controls the amount of the wrap-around artifacts and the duration, and wherein the PFOV and the duration increases as the reduced value increases.

15. The MRI system of claim 11, wherein the NPW protocol comprises applying, by the control component, a NPW parameter value that controls a phase field-of-view (PFOV) of the signal data in a phase encoding direction of the 2D MRI process, and wherein the OVS protocol comprises employing, by the control component, a pulse sequence that comprises one or two radio frequency (RF) pulses configured to suppress magnetic resonance signals in one or more volume regions of the anatomical region outside the ROI in the phase encoding direction.

16. The MRI system of claim 15, wherein a value of the NPW parameter is variable, and wherein the PFOV and a duration of the acquisition of the signal data increases as the value increases.

17. The MRI system of claim 15, wherein the ROI corresponds to a portion of a target anatomical object, and wherein the computer-executable components further comprise:
a configuration component that determines the NPW parameter value and a spatial position of the one or more volume regions in the phase encoding direction based on the ROI, a total length of the target anatomical object in the phase encoding direction, and in accordance with defined optimization criteria, the defined optimization criteria comprising balancing minimizing a duration of the acquisition of the signal data and minimizing an amount of wrap-around artifacts included in the image.

18. The MRI system of claim 15, wherein the ROI corresponds to a portion of a target anatomical object, and wherein the computer-executable components further comprise:
a configuration component that:
selects a NPW parameter value that corresponds to the PFOV being less than a total length of the target anatomical object in the phase encoding direction; and
determines a spatial position of the one or more volume regions in the phase encoding direction based on the ROI, the total length of the target anatomical object in the phase encoding direction, and the NPW parameter value.

19. The MRI system of claim 11, wherein the 2D MRI process is selected from the group consisting of: a spin echo process, a fast spin echo process, and a turbo spin echo process.

20. A non-transitory machine-readable storage medium, comprising executable instructions that, when executed by a processor, facilitate performance of operations, comprising:
controlling acquisition of a signal data associated with a region of interest within an anatomical region of a subject using a using a magnetic resonance imaging (MRI) system, wherein the controlling comprises employing a combination of an outer volume suppression (OVS) protocol and a no phase wrap (NPW) protocol with a two-dimensional (2D) MRI process; and
reconstructing an image of the ROI from the signal data.
